(19) United States
(12) Patent Application Publication
(10) Pub. No.: US 2019/0334101 A1
(43) Pub. Date: Oct. 31, 2019

(54) METHOD OF FABRICATING FLEXIBLE BACK-SUBSTRATE, FLEXIBLE BACK-SUBSTRATE, AND FLEXIBLE DISPLAY APPARATUS

(71) Applicant: WUHAN CHINA STAR OPTOELECTRONICS SEMICONDUCTOR DISPLAY TECHNOLOGY CO., LTD., Wuhan, Hubei (CN)

(72) Inventor: Lun SHANG, Wuhan, Hubei (CN)

(21) Appl. No.: 16/091,118

(22) PCT Filed: Aug. 27, 2018
(86) PCT No.: PCT/CN2018/102395

§ 371 Date: Oct. 4, 2018

(30) Foreign Application Priority Data
Apr. 27, 2018 (CN) 201810391400.8

(51) Int. Cl. H01L 51/00; H01L 27/32; H01L 51/56

(52) U.S. Cl. CPC H01L 51/0097; H01L 2251/5338; H01L 51/56; H01L 27/3244

(57) ABSTRACT

A method of fabricating a flexible back-substrate, a flexible back-substrate and a flexible display apparatus are provided. The method of fabricating the flexible back-substrate has: providing a back-substrate; forming a plurality of protrusions spaced apart from each other on a surface of the back-substrate; and filling a photoresist material between the plurality of protrusions to form a flexible layer.

### FIELD OF DISCLOSURE

The present disclosure relates to a technical field of displays, and more particularly to a method of fabricating a flexible back-substrate, a flexible back-substrate, and a flexible display apparatus.

### BACKGROUND OF DISCLOSURE

With rapid development of mobile terminals such as mobile phones and tablet PCs, demand for flat panel displays has become higher and higher. The flat panel displays include a super twisted nematic liquid crystal display (STN-LCD), a thin film transistor liquid crystal display (TFT-LCD), a plasma display panel (PDP), and other types of monitors. An organic light emitting display (OLED) or an organic electroluminescent display has advantages of self-luminescence, no need for a backlight plate, low power consumption, and the like, and has been widely used.

Among them, flexible OLEDs not only have all the advantages of OLED, but also have flexible displaying characteristics. However, conventional flexible OLEDs have poor bending performance due to material restrictions.

### Technical Problem

An object of the present disclosure is to provide a method of fabricating a flexible back-substrate, a flexible back-substrate and a flexible display apparatus, which can improve flexibility of the back-substrate and the flexible display apparatus.

### Technical Solutions

An embodiment of the present disclosure provides a method of fabricating a flexible back-substrate, comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

In some embodiments, the step of forming the plurality of protrusions on the surface of the back-substrate where the plurality of protrusions are disposed and spaced apart from each other comprises a step of: etching the surface of the back-substrate to form the plurality of protrusions.

In some embodiments, the step of etching the surface of the back-substrate to form the plurality of protrusions comprises: wet-etching the surface of the back-substrate to form the plurality of protrusions.

In some embodiments, a bending radius of the flexible back-substrate ranges from 0.09 mm to 0.11 mm.

In some embodiments, a thickness of the flexible layer ranges from 0.085 mm to 0.1 mm.

In some embodiments, the back-substrate is a hollow structure.

An embodiment of the present disclosure further provides a flexible back-substrate fabricated using a fabricating method comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

In some embodiments, the step of forming the plurality of protrusions on the surface of the back-substrate where the plurality of protrusions are disposed and spaced apart from each other comprises a step of: etching the surface of the back-substrate to form the plurality of protrusions.

In some embodiments, the step of etching the surface of the back-substrate to form the plurality of protrusions comprises: wet-etching the surface of the back-substrate to form the plurality of protrusions.

In some embodiments, a bending radius of the flexible back-substrate ranges from 0.09 mm to 0.11 mm.

In some embodiments, a thickness of the flexible layer ranges from 0.085 mm to 0.1 mm.

In some embodiments, the back-substrate is a hollow structure.

An embodiment of the present disclosure further provides a flexible display apparatus, comprising a flexible back-substrate and an organic electroluminescent device, wherein the organic electroluminescent device is disposed on a flexible layer of the flexible back-substrate, and the flexible back-substrate fabricated using a fabricating method comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

In some embodiments, the step of forming the plurality of protrusions on the surface of the back-substrate where the plurality of protrusions are disposed and spaced apart from each other comprises a step of: etching the surface of the back-substrate to form the plurality of protrusions.

In some embodiments, the step of etching the surface of the back-substrate to form the plurality of protrusions comprises: wet-etching the surface of the back-substrate to form the plurality of protrusions.

In some embodiments, a bending radius of the flexible back-substrate ranges from 0.09 mm to 0.11 mm.

In some embodiments, a thickness of the flexible layer ranges from 0.085 mm to 0.1 mm.

In some embodiments, the flexible display apparatus further comprises a buffer layer disposed on a side of the flexible back-substrate away from the organic electroluminescent device.

In some embodiments, a constituent material of the buffer layer includes a foam material.

In some embodiments, a bending radius of the flexible display apparatus ranges from 0.3 mm to 0.5 mm.

### Beneficial Effect

In a method of fabricating a flexible back-substrate, a flexible back-substrate and a flexible display apparatus in some embodiments of the present disclosure, a plurality of protrusions are formed on a surface of the back-substrate and then a photoresist material is filled between the plurality of protrusions to form a flexible layer, so as to improve flexibility of the back-substrate and the flexible display apparatus.

### DESCRIPTION OF DRAWINGS

To make the above description of the present disclosure more clearly comprehensible, it is described in detail below in examples of preferred embodiments with the accompanying drawings.

FIG. 1 is a schematic flow-chart of a method of fabricating a flexible back-substrate provided by an embodiment of the present disclosure.

FIG. 2 is a scene schematic diagram of a method of fabricating a flexible back-substrate provided by an embodiment of the present disclosure.

FIG. 3 is a structural schematic diagram of a flexible back-substrate provided by an embodiment of the present disclosure.

FIG. 4 is a structural schematic diagram of a flexible display apparatus provided by an embodiment of the present disclosure.

### BEST EMBODIMENTS OF PRESENT DISCLOSURE

The following description of various embodiments refers to the accompanying drawings for the purpose of illustrating certain embodiments in which the disclosure can be practiced. Directional terms described by the present disclosure, such as upper, lower, front, back, left, right, inner, outer, side, and etc., are only directions by referring to the accompanying drawings, and thus the used directional terms are used to describe and understand the present disclosure, but the present disclosure is not limited thereto.

In the drawings, elements with similar structures are represented by the same reference numerals.

References herein to “embodiment” mean that a particular feature, structure, or characteristic described in connection with an embodiment can be included in at least one embodiment of the present disclosure. The appearances of such phrases in various places in the specification are not necessarily all referring to the same embodiment, nor are separate or alternative embodiments mutually exclusive of other embodiments. It will be understood by those skilled in the art, both explicitly and implicitly, that the embodiments described herein can be combined with other embodiments.

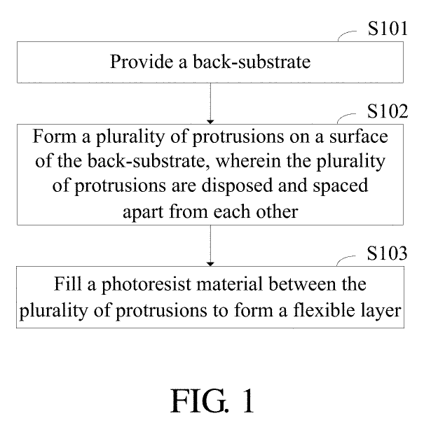

An embodiment of the present embodiment provides a method of fabricating a flexible back-substrate. Refer to FIG. 1, which is a schematic flow-chart of a method of fabricating a flexible back-substrate provided by an embodiment of the present disclosure.

In step S101, a back-substrate is provided.

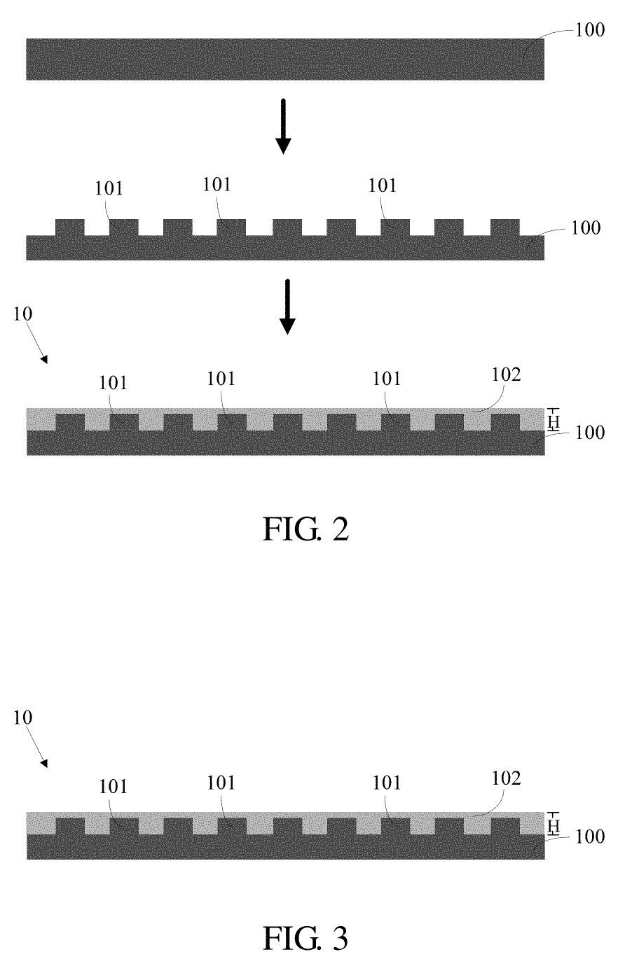

As illustrated in FIG. 2, a back-substrate 100 is provided, where a constituent material of the back-substrate 100 can include polyimide (PI). A thickness of the back-substrate 100 can range around 0.1 mm, preferably range from 0.085 mm to 0.11 mm. Preferably, the back-substrate 100 can be configured as a hollow structure to reduce the stress on the back-substrate 100 when being bent.

In step S102, a plurality of protrusions are formed on a surface of the back-substrate, wherein the plurality of protrusions are disposed and spaced apart from each other.

In some embodiments, a plurality of protrusions 101 can be first formed, and then the plurality of protrusions 101 are fixed onto the surface of the back-substrate 100. In some embodiments, as illustrated in FIG. 2, the back-substrate 100 can be etched for performing a patterning treatment on the back-substrate 100, so as to form the plurality of protrusions 101 on the surface of the back-substrate 100, wherein the plurality of protrusions 101 are disposed and spaced apart from each other.

A dry etching or a wet etching process can be used to etch the back-substrate 100. Preferably, the back-substrate 100 can be etched using a wet etching process so as to prevent a photoresist material from overflowing when the back-substrate 100 is bent.

In step S103, a photoresist material is filled between the plurality of protrusions to form a flexible layer.

Finally, a photoresist material is filled between the plurality of protrusions 101 to form a flexible layer 102, where a thickness H of the flexible layer 102 ranges from 0.085 mm to 0.1 mm. The flexible back-substrate 10 can be fabricated using the above method. When bending the flexible back-substrate 10, a bending radius of the flexible back-substrate 10 ranges from 0.09 mm to 0.11 mm.

In a method of fabricating a flexible back-substrate in some embodiments of the present disclosure, a plurality of protrusions are formed on a surface of the back-substrate and then a photoresist material is filled between the plurality of protrusions to form a flexible layer, so as to improve flexibility of the flexible back-substrate.

According to the method of fabricating the flexible back-substrate described in the above embodiments, the present embodiment will be further described from the perspective of the flexible back-substrate, wherein the flexible back-substrate is fabricated by the above method.

Refer to FIG. 3, which is a flexible back-substrate provided by an embodiment of the present disclosure. As illustrated in FIG. 3, the flexible back-substrate 10 includes a back-substrate 100, a plurality of protrusions 101, and a flexible layer 102, where the plurality of protrusions 101 are disposed and spaced apart from each other, and the flexible layer 102 is formed by filling a photoresist material between the plurality of protrusions 101.

A constituent material of the back-substrate 100 can include polyimide (PI). A thickness of the back-substrate 100 can range around 0.1 mm, preferably range from 0.085 mm to 0.11 mm. Preferably, the back-substrate 100 can be configured as a hollow structure to reduce the stress on the back-substrate 100 when being bent.

In some embodiments, a plurality of protrusions 101 can be first formed, and then the plurality of protrusions 101 are fixed onto the surface of the back-substrate 100. In some embodiments, as illustrated in FIG. 2, the back-substrate 100 can further be etched for performing a patterning treatment on the back-substrate 100, so as to form the plurality of protrusions 101 on the surface of the back-substrate 100, wherein the plurality of protrusions 101 are disposed and spaced apart from each other.

A dry etching or a wet etching process can be used to etch the back-substrate 100. Preferably, the back-substrate 100 can be etched using a wet etching process so as to prevent a photoresist material from overflowing when the back-substrate 100 is bent.

The flexible layer 102 is formed by filling the photoresist material between the plurality of protrusions 101, where a thickness H of the flexible layer 102 ranges from 0.085 mm to 0.1 mm. When bending the flexible back-substrate 10, a bending radius of the flexible back-substrate 10 ranges from 0.09 mm to 0.11 mm.

It is noted that, the flexible back-substrate 10 can be applied to a display apparatus, and can also be applied to a non-display apparatus to improve the flexibility of the display apparatus or the non-display apparatus.

In a flexible back-substrate in some embodiments of the present disclosure, a plurality of protrusions are formed on a surface of the back-substrate and then a photoresist material is filled between the plurality of protrusions to form a flexible layer, so as to improve flexibility of the flexible back-substrate.

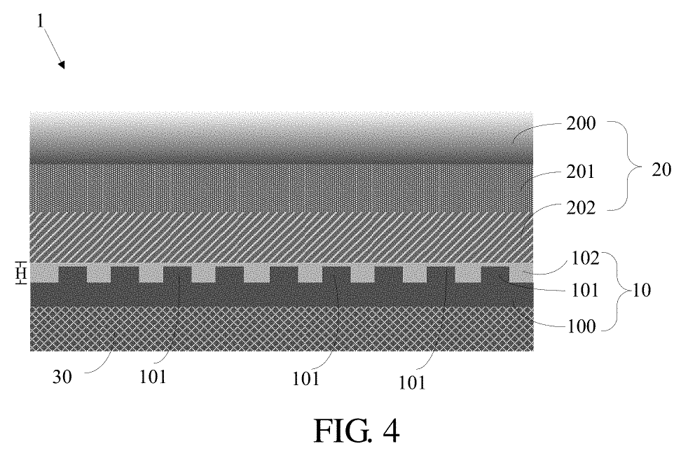

An embodiment of the present disclosure provides a flexible display apparatus. Refer to FIG. 4, which is a structural schematic diagram of a flexible display apparatus provided by an embodiment of the present disclosure. The flexible display apparatus 1 includes a flexible back-substrate 10 and an organic electroluminescent device 20, wherein the organic electroluminescent device 20 is disposed on a flexible layer 102 of the flexible back-substrate 10.

As illustrated in FIG. 4, the organic electroluminescent device 20 includes an organic light emitting layer 200, a thin film transistor 201, and a substrate 202 disposed and stacked in sequence.

The flexible back-substrate 10 includes a back-substrate 100, a plurality of protrusions 101, and a flexible layer 102, where the plurality of protrusions 101 are disposed and spaced apart from each other, and the flexible layer 102 is formed by filling a photoresist material between the plurality of protrusions 101.

A constituent material of the back-substrate 100 can include polyimide (PI). A thickness of the back-substrate 100 can range around 0.1 mm, preferably range from 0.085 mm to 0.11 mm. Preferably, the back-substrate 100 can be configured as a hollow structure to reduce the stress on the back-substrate 100 when being bent.

In some embodiments, a plurality of protrusions 101 can be first formed, and then the plurality of protrusions 101 are fixed onto the surface of the back-substrate 100. In some embodiments, as illustrated in FIG. 2, the back-substrate 100 can further be etched for performing a patterning treatment on the back-substrate 100, so as to form the plurality of protrusions 101 on the surface of the back-substrate 100, wherein the plurality of protrusions 101 are disposed and spaced apart from each other.

A dry etching or a wet etching process can be used to etch the back-substrate 100. Preferably, the back-substrate 100 can be etched using a wet etching process so as to prevent a photoresist material from overflowing when the back-substrate 100 is bent.

The flexible layer 102 is formed by filling the photoresist material between the plurality of protrusions 101, where a thickness H of the flexible layer 102 ranges from 0.085 mm to 0.1 mm. When bending the flexible back-substrate 10, a bending radius of the flexible back-substrate 10 ranges from 0.09 mm to 0.11 mm.

Preferably, the flexible layer 102 not only is disposed between the plurality of protrusions 101, but also covers with surfaces of the plurality of protrusions 101. As illustrated in FIG. 4, for the organic electroluminescent device 20 disposed on the flexible back-substrate 10, the organic electroluminescent device 20 can be fixed on the flexible layer 102 by virtue of an adhesive property of the photoresist material in the flexible layer 102.

In some embodiments, the flexible display apparatus 1 further includes a buffer layer 30. The buffer layer 30 is disposed on a side of the flexible back-substrate 10 away from the organic electroluminescent device 20, where a constituent material of the buffer layer includes a foam material. When the flexible display apparatus 1 is bent, the buffer layer 30 can reduce the stress applied to the flexible display apparatus 1.

When the flexible apparatus 1 is assembled, the organic electroluminescent device 20 can be first fixed on the flexible back-substrate 10 by virtue of the adhesive property of the flexible layer 102, and then the buffer layer 30 is fixed on the side of the flexible back-substrate 10 away from the organic electroluminescent device 20. The flexible display device 1 fabricated by the above method has a bending radius ranging from 0.3 mm to 0.5 mm.

In a flexible display apparatus in some embodiments of the present disclosure, a plurality of protrusions are formed on a surface of the back-substrate and then a photoresist material is filled between the plurality of protrusions to form a flexible layer, so as to improve flexibility of the flexible display apparatus.

As described above, although the present disclosure has been disclosed in the preferred embodiments as above, the above preferred embodiments are not intended to limit the present disclosure. Those skilled in the art can make various changes and modifications without departing from the spirit and scope of the present disclosure. Therefore, the protection scope of the present disclosure is defined by the scope of the claims.

1. A method of fabricating a flexible back-substrate, comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

2. The method of fabricating the flexible back-substrate according to claim 1, wherein the step of forming the plurality of protrusions on the surface of the back-substrate where the plurality of protrusions are disposed and spaced apart from each other comprises a step of: etching the surface of the back-substrate to form the plurality of protrusions.

3. The method of fabricating the flexible back-substrate according to claim 2, wherein the step of etching the surface of the back-substrate to form the plurality of protrusions comprises: wet-etching the surface of the back-substrate to form the plurality of protrusions.

4. The method of fabricating the flexible back-substrate according to claim 1, wherein a bending radius of the flexible back-substrate ranges from 0.09 mm to 0.11 mm.

5. The method of fabricating the flexible back-substrate according to claim 1, wherein a thickness of the flexible layer ranges from 0.085 mm to 0.1 mm.

6. The method of fabricating the flexible back-substrate according to claim 1, wherein the back-substrate is a hollow structure.

7. A flexible back-substrate fabricated using a fabricating method comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

8. The flexible back-substrate according to claim 7, wherein the step of forming the plurality of protrusions on the surface of the back-substrate where the plurality of protrusions are disposed and spaced apart from each other comprises a step of: etching the surface of the back-substrate to form the plurality of protrusions.

9. The flexible back-substrate according to claim 8, wherein the step of etching the surface of the back-substrate to form the plurality of protrusions comprises: wet-etching the surface of the back-substrate to form the plurality of protrusions.

10. The flexible back-substrate according to claim 7, wherein a bending radius of the flexible back-substrate ranges from 0.09 mm to 0.11 mm.

11. The flexible back-substrate according to claim 7, wherein a thickness of the flexible layer ranges from 0.085 mm to 0.1 mm.

12. The flexible back-substrate according to claim 7, wherein the back-substrate is a hollow structure.

13. A flexible display apparatus, comprising a flexible back-substrate and an organic electroluminescent device, wherein the organic electroluminescent device is disposed on a flexible layer of the flexible back-substrate, and the flexible back-substrate fabricated using a fabricating method comprising steps of:
providing a back-substrate;
forming a plurality of protrusions on a surface of the back-substrate, wherein the plurality of protrusions are disposed and spaced apart from each other; and
filling a photoresist material between the plurality of protrusions to form a flexible layer.

14. The flexible display apparatus according to claim 13, wherein the step of forming the plurality of protrusions on the surface of the back-substrate where the plurality of protrusions are disposed and spaced apart from each other comprises a step of: etching the surface of the back-substrate to form the plurality of protrusions.

15. The flexible display apparatus according to claim 14, wherein the step of etching the surface of the back-substrate to form the plurality of protrusions comprises: wet-etching the surface of the back-substrate to form the plurality of protrusions.

16. The flexible display apparatus according to claim 13, wherein a bending radius of the flexible back-substrate ranges from 0.09 mm to 0.11 mm.

17. The flexible display apparatus according to claim 13, wherein a thickness of the flexible layer ranges from 0.085 mm to 0.1 mm.

18. The flexible display apparatus according to claim 13, further comprising a buffer layer disposed on a side of the flexible back-substrate away from the organic electroluminescent device.

19. The flexible display apparatus according to claim 13, wherein a constituent material of the buffer layer includes a foam material.

20. The flexible display apparatus according to claim 13, wherein a bending radius of the flexible display apparatus ranges from 0.3 mm to 0.5 mm.
